(19) United States
(12) Patent Application Publication
(10) Pub. No.: US 2023/0420989 A1
(43) Pub. Date: Dec. 28, 2023

(54) DEVICE-TO-DEVICE BASED WIRELESS POWER RECEIVING DEVICE AND METHOD

(71) Applicant: SKAIChips Co., Ltd., Suwon-si (KR)

(72) Inventors: Kang Yoon LEE, Seoul (KR); Sung June BYUN, Suwonsi (KR); Jong Wan JO, Suwon-si (KR); Ji Hoon SONG, Suwon-si (KR); Young Gun PU, Suwon-si (KR)

(73) Assignee: SKAIChips Co., Ltd., Suwon-si (KR)

(21) Appl. No.: 18/215,413

(22) Filed: Jun. 28, 2023

(30) Foreign Application Priority Data
Jun. 28, 2022 (KR) 10-2022-0079136

(51) Int. Cl. H02J 50/10; H02J 50/90

(52) U.S. Cl. CPC H02J 50/10; H02J 50/90

(57) ABSTRACT

Provided is a device-to-device (D2D)-based wireless power receiving device including an observation part configured to monitor a battery, an estimator configured to estimate usage and a workload of the battery on the basis of a result of monitoring the battery, a mode determiner configured to determine required power of the battery on the basis of the usage and the workload, and determine a reception mode according to the required power, and a power receiver configured to wirelessly receive power from another device according to the reception mode. Accordingly, wireless power charging efficiency can be maximized.

### CROSS-REFERENCE TO RELATED APPLICATION(S)

This application claims priority from Korean Patent Application No. 10-2022-0079136, filed on Jun. 28, 2022, in the Korean Intellectual Property Office, the disclosure of which is incorporated herein by reference in its entirety.

### BACKGROUND

### 1. Field

The following description relates to a device-to-device (D2D)-based wireless power receiving device and method, and more particularly, to a D2D-based wireless power receiving device and method for wirelessly receiving power in a D2D manner.

### 2. Description of Related Art

Recently, the number of Internet of Things (I) devices has been exponentially increasing with the development of IoT technology.

Such an IoT device is a device that includes a power source, a communication chipset, and a processor therein, and may collect various types of data at a position at which the IoT device is installed and transmit collected data using an IoT communication network, a mobile communication network or the like.

In addition, the IoT device performs a designated function according to control data received through the IoT communication network, the mobile communication network or the like.

As described above, it is necessary to supply power to the communication chipset and the processor or charge a power source so that the IoT device may continuously operate normally.

In this regard, a wired charging method of the related art is disadvantageous in that a charging line should be connected to an IoT device and the mobility of the IoT device is limited.

To solve this problem, a short-range wireless charging system has been introduced, but is disadvantageous in that a charging distance is limited and only IoT devices including only one transmitting (TX) coil and only one receiving coil can be charged.

As another alternative method, a long-distance wireless charging system using a radio-frequency (RF) signal has been introduced but is disadvantageous in that the location of an IoT device should be detected, thus leading to inevitable power consumption, and power waste is severe when the accuracy of beam steering is low.

Therefore, there is a need to research and develop a technique for minimizing power consumption and efficiently receiving power when the IoT device performs charging wirelessly.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

To address the above-described problems, the following description provides a device-to-device (D2D)-based wireless power receiving device and method for wirelessly receiving power from other devices by monitoring an internal battery and selecting a reception mode according to a result of monitoring the internal battery.

In one general aspect, a wireless power receiving device based on D2D includes an observation part configured to monitor a battery, an estimator configured to estimate usage and a workload of the battery on the basis of a result of monitoring the battery, a mode determiner configured to determine required power of the battery on the basis of the usage and the workload, and determine a reception mode according to the required power, and a power receiver configured to wirelessly receive power from another device according to the reception mode.

Here, the observation part may monitor the battery by checking remaining capacity of the battery at certain time intervals.

In this regard, the mode determiner may output the required power by inputting the usage and the workload to a deep learning-based required-power output model.

In this case, the reception mode may include an emergency mode for requesting the other device to provide the required power through a short-range reception mode, a normal mode for requesting the other device to provide the required power through a long-range reception mode, and a rejection mode for rejecting the required power from the other device.

Next, the mode determiner may compare the required power with a threshold range when the required-power output model outputs the required power, and operate the wireless power receiving device in the emergency mode when the required power is beyond the threshold range, operate the wireless power receiving device in the normal mode when the required power is in the threshold range, and operate the wireless power receiving device in the rejection mode when the required power is below the threshold range.

In another general aspect, a wireless power receiving method, performed by a D2D-based wireless power receiving device, includes an observation operation of monitoring a battery, an estimation operation of estimating usage and a workload of the battery on the basis of a result of monitoring the battery, a mode determination operation of determining required power of the battery on the basis of the usage and the workload, and determining a reception mode according to the required power, and a power receiving operation of wirelessly receiving power from another device according to the reception mode.

Here, the observation operation may include monitoring the battery by checking remaining capacity of the battery at certain time intervals.

In this regard, the mode determination operation may include outputting the required power by inputting the usage and the workload to a deep learning-based required-power output model.

In this case, the reception mode may include an emergency mode for requesting the other device to provide the required power through a short-range reception mode, a normal mode for requesting the other device to provide the required power through a long-range reception mode, and a rejection mode for rejecting the required power from the other device.

The mode determination operation may include comparing the required power with a threshold range when the required-power output model outputs the required power, and operating the wireless power receiving device in the emergency mode when the required power is beyond the threshold range, operating the wireless power receiving device in the normal mode when the required power is in the threshold range, and operating the wireless power receiving device in the rejection mode when the required power is below the threshold range.

Other features and aspects will be apparent from the following detailed description, the drawings, and the claims.

### BRIEF DESCRIPTION OF THE DRAWINGS

FIG. 1 is a diagram illustrating an example of a device-to-device (D2D) system including a wireless power receiving device according to an embodiment of the present disclosure.

FIG. 2 is a block diagram of a wireless power receiving device according to an embodiment of the present disclosure.

FIG. 3 is a detailed block diagram of a power receiver of FIG. 2.

FIGS. 4 and 5 are flowcharts of a wireless power receiving method according to an embodiment of the present disclosure.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, the present disclosure will be described in detail with respect to embodiments thereof as examples with reference to the accompanying drawings. These embodiments will be described herein in sufficient detail to enable those of ordinary skill in the art to practice the present disclosure. It should be understood that various embodiments of the present disclosure are different from each other but need not be mutually exclusive. For example, specific shapes, structures and characteristics described herein may be implemented in different embodiments without departing from the spirit and scope of the present disclosure in connection with an embodiment. In addition, it should be understood that the position or arrangement of each element in each embodiment set forth herein may be changed without departing from the spirit and scope of the present disclosure. Therefore, the following detailed description is not intended to restrict the present disclosure, and the scope of the present disclosure should be limited only by the appended claims, including all ranges equivalent to that defined in the claims when appropriately described. In the drawings, like reference numerals represent the same or similar functions in various aspects.

The features and advantages of the present disclosure will become more apparent from the detailed description based on the accompanying drawings. The terms or expressions used in the present specification and the claims should not be construed as being limited to as generally understood or as defined in commonly used dictionaries, and should be understood according to the technical idea of the present disclosure, based on the principle that the inventor(s) of the application can appropriately define the terms or expressions to optimally explain the present disclosure.

Hereinafter, example embodiments of the present disclosure will be described in detail with reference to the accompanying drawings.

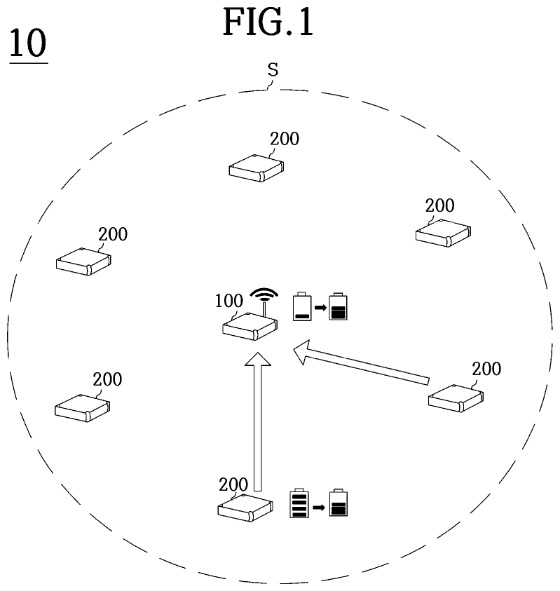

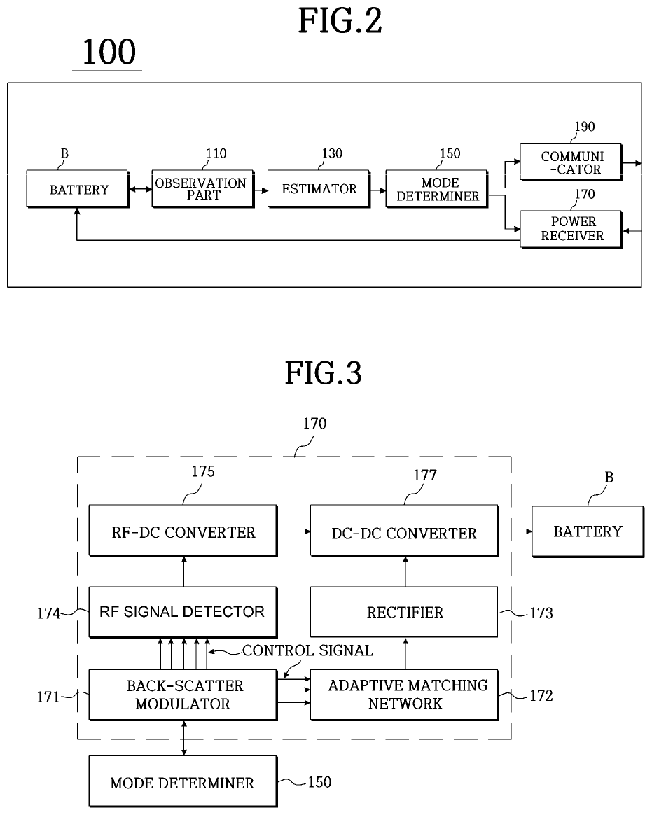

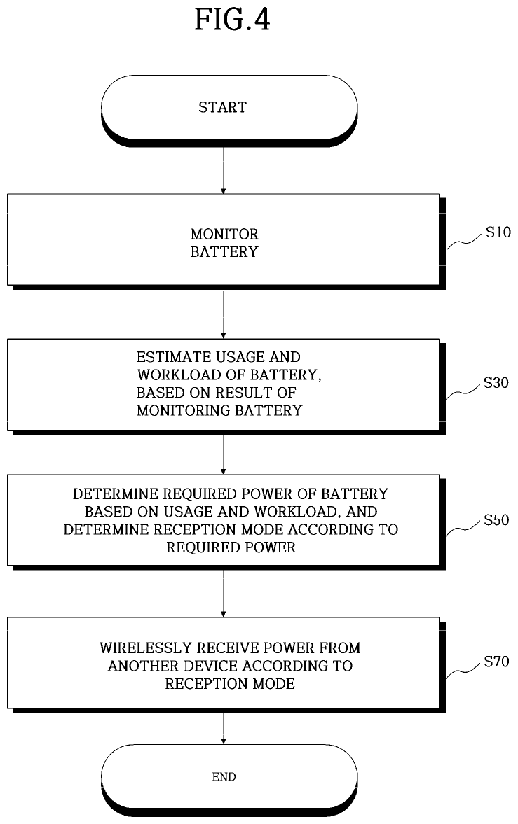

FIG. 1 is a diagram illustrating an example of a device-to-device (D2D) system including a D2D-based wireless power receiving device according to an embodiment of the present disclosure. FIG. 2 is a block diagram of a wireless power receiving device according to an embodiment of the present disclosure. FIG. 3 is a detailed block diagram of a power receiver of FIG. 2.

Referring to FIG. 1, in a D2D system 10 according to the embodiment of the present disclosure, a spatial map S is formed in advance, and a D2D-based wireless power receiving device (hereinafter referred to as the wireless power receiving device) 100 according to the embodiment of the present disclosure and at least one wireless power transmitting device (hereinafter referred to as the other device) 200 that wirelessly transmits power to the wireless power receiving device 100 are provided.

The D2D system 10 is a system that allows adjacent terminals to directly transmit and receive information and power to and from each other without an infrastructure such as a base station, and may be embodied as Bluetooth, FlashLinQ, Wi-Fi Direct, or the like.

The D2D system 10 may be provided as a distributed communication environment to allow information or power to be transmitted and received between the wireless power receiving device 100 and the other device 200.

Here, the D2D system 10 may be applied to multiple places regardless of a place or environment.

For example, the D2D system 10 may be applied to production facilities such as factories, business sites, and working places, equipment, residences such as apartments and detached houses, or public places.

Accordingly, the wireless power receiving device 100 may have mobility or be fixed. The wireless power receiving device 100 may be in the form of a server or engine, and may be referred to as a different term such as an apparatus, a terminal, a user equipment (UE), a mobile station (MS), a wireless device, or a hand-held device.

The wireless power receiving device 100 may allow various types of software to be executed or manufactured on the basis of an operating system (OS), i.e., the system. The OS is a system program for allowing hardware of a device to be used in software, and examples may include both mobile computer OSs such as Android OS, iOS, Windows Mobile OS, Bada OS, Symbian OS, and Blackberry OS, and computer OSs such as Windows, Linux, Unix, MAC, AIX, and HP-UX.

Thus, the wireless power receiving device 100 may include an observation part 110, an estimator 130, a mode determiner 150, a power receiver 170, and a communicator 190 to perform a wireless power receiving method of wirelessly receiving power from the other device 200.

Software (an application) for performing a wireless power receiving method may be installed and executed in the wireless power receiving device 100, and the observation part 110, the estimator 130, the mode determiner 150, the power receiver 170, and the communicator 190 may be controlled by the software for performing the wireless power receiving method that is performed by the wireless power receiving device 100.

Although not shown, the wireless power receiving device 100 may further include a storage part in which a deep learning-based model used by the wireless power receiving device 100, monitoring results produced as the observation part 110 monitors a battery B, usage estimated by the estimator 130, a workload, and a spatial map S set in advance by a user are stored, and the storage part may also be controlled by the software for performing the wireless power receiving method performed by the wireless power receiving device 100.

The wireless power receiving device 100 may be a separate terminal or module. The observation part 110, the estimator 130, the mode determiner 150, the power receiver 170, and the communicator 190 may be formed as an integrated module or one or more modules. On the other hand, these components may be separate modules.

In the wireless power receiving device 100, a transceiver circuit may be provided to receive power from at least another device 200 included in the D2D system 10.

Here, the transceiver circuit is an electrical circuit for transmitting and receiving a power signal, and may be provided as a circuit module corresponding to the power receiver 170 and receiving power from the other device 200.

Accordingly, the wireless power receiving device 100 may wirelessly receive a power signal from the other device 200 through the power receiver 170 and independently supply power.

The power receiver 170 will be described in detail below to facilitate the understanding of the present disclosure.

Meanwhile, the wireless power receiving device 100 may receive power from the other device 200 by a single tone modulation method using in-phase/quadrature (I/Q) modulation based on the orthogonality of a channel.

Alternatively, the wireless power receiving device 100 may receive power from the other device 200 by peak-to-average power ratio (PARP)-based SWIPT (hereinafter referred to as a PAPR transmission technique) of transmitting information and energy using a multi-tone signal.

Here, the PARP transmission technique is a technique for transmitting information using a PARP and using multiple tones to increase the efficiency of wireless power transmission.

The wireless power receiving device 100 that wirelessly receives power from the other device 200 using the single tone modulation method or the PARP transmission technique will be described with reference to FIGS. 2 and 3 in detail below.

Referring to FIG. 2, the wireless power receiving device 100 includes an observation part 110, an estimator 130, a mode determiner 150, a power receiver 170, and a communicator 190.

First, the observation part 110 monitors a battery B.

More specifically, the observation part 110 may check and monitor remaining capacity of the battery B at certain time intervals.

Here, the observation part 110 may output a result of checking the remaining capacity of the battery B at the certain time intervals in the form of a graph or output information about a time when the battery B is checked and remaining capacity of the battery B according to the time in the form of a table.

In addition, the observation part 110 may transmit an output monitoring result obtained by monitoring the battery B at the certain time intervals to the storage part or the estimator 130.

In this regard, the estimator 130 estimates usage and a workload of the battery B on the basis of the result of monitoring the battery B.

More specifically, the estimator 130 may estimate, as usage, a capacity calculated as the difference between a remaining capacity checked at a time interval and a remaining capacity checked at a subsequent time interval, which are included in the monitoring result received from the observation part 110.

In this case, the estimator 130 may add capacities calculated as the difference between remaining capacities checked at time intervals and remaining capacities checked at subsequent time intervals, and estimate a capacity calculated by dividing the sum of the capacities by the number of time intervals as usage per time.

In addition, the estimator 130 may compare a remaining capacity checked at a time interval with a remaining capacity checked at a subsequent time interval, which are included in the monitoring result received from the observation part 110.

More specifically, the estimator 130 may compare a remaining capacity checked at a time interval with a remaining capacity checked at a subsequent time interval, which are included in the monitoring result, and determine that the wireless power receiving device 100 is used by a user and thus estimate a workload, when the remaining capacity checked at the subsequent time interval is less than the remaining capacity checked at the time interval.

Here, the workload is a work load rate, i.e., data indicating an increase in data to be processed by a user using the wireless power receiving device 100.

The estimator 130 may estimate usage and a workload of the battery B on the basis of the monitoring result received from the observation part 110 and may transmit the estimated usage and workload to the mode determiner 150.

In this regard, the mode determiner 150 determines required power of the battery B on the basis of the usage and the workload.

In addition, the mode determiner 150 determines a reception mode according to the required power.

More specifically, the mode determiner 150 may output required power by inputting the usage and the workload of the battery B that are estimated by the estimator 130 to a deep learning-based required-power output model.

Here, the mode determiner 150 may train a long short-term memory (LSTM) algorithm with training data including remaining capacity, usage, and a workload of the battery B to generate a required-power output model that outputs required power as an output value when data is input thereto.

Here, the mode determiner 150 may use the LSTM algorithm to generate the required-power output model but is not limited thereto and may use a well-known deep learning-based algorithm such as the recurrent neural network (RNN) algorithm, a feed-forward neural network (FNN) algorithm, or a convolution neural network (CNN) algorithm.

Meanwhile, the mode determiner 150 may compare the required power output from the required-power output model with a preset threshold range to determine a reception mode.

Here, the reception mode may include an emergency mode for requesting the other device 200 to provide the required power through a short-range reception mode, a normal mode for requesting the other device 200 to provide the required power through a long-distance reception mode, and a rejection mode for rejecting the required power from the other device 200.

More specifically, the mode determiner 150 may compare the required power output from the required-power output model with the threshold range, and determine the emergency mode as the reception mode and operate the wireless power receiving device 100 in the emergency mode when the required power is beyond the threshold range.

In this case, the mode determiner 150 may generate an emergency request message requesting the required power by a short-range reception method according to the determined emergency mode to request the other device 200 to provide the required power.

As the wireless power receiving device 100 operates in the emergency mode, the mode determiner 150 may operate the power receiver 170 in the short-range reception mode.

The short-range reception mode is a method of receiving power by a magnetic induction reception method, a magnetic resonance reception method, or antenna radiation.

Meanwhile, the mode determiner 150 may determine the normal mode as the reception mode and operate the wireless power receiving device 100 in the normal mode when the required power output from the required-power model is in the threshold range.

In this case, the mode determiner 150 may generate a normal request message requesting the required power by a long-range reception method according to the determined normal mode to request the other device 200 to provide the required power.

As the wireless power receiving device 100 operates in the normal mode, the mode determiner 150 may operate the power receiver 170 in a long-range reception mode.

Here, the long-distance transmission method is a method of receiving power by a radio-frequency (RF) reception method of receiving a power signal through a high frequency of 300 MHz or higher.

Meanwhile, the mode determiner 150 may determine the rejection mode as the reception mode and operate the wireless power receiving device 100 in the rejection mode when the required power output from the required-power model is below the threshold range.

In this case, according to the determined rejection mode, the mode determiner 150 may generate a rejection message rejecting the required power because remaining capacity of the battery B is sufficient.

As the wireless power receiving device 100 operates in the rejection mode, the mode determiner 150 may operate the power receiver 170 in a reception rejection mode.

Here, the reception rejection mode may be either a standby mode in which the required power received from the other device 200 is not stored in the battery B and is maintained as standby power or a reception rejection mode in which the required power is not received from the other device 200.

Meanwhile, the power receiver 170 receives power from the other device 200 according to the reception mode.

Referring to FIG. 3, the power receiver 170 may be provided as a transceiver circuit including a back-scatter modulator 171 to wirelessly receive power from the other device 200.

Here, the back-scatter modulator 171 may generate an AM signal using a tone frequency according to a control signal received from the other device 200 to store the control signal in the battery B.

More specifically, the back-scatter modulator 171 may generate a tone frequency AM signal, including bits of an identifier, a received power signal, and a stored power signal, according to an amplitude-magnitude control signal by a (bit) encoding method agreed upon with the other device 200.

In this regard, the power receiver 170 may be provided as a transceiver circuit further including an adaptive matching network 172, a rectifier 173, an RF signal detector 174, an RF-DC converter 175, and a DC-DC converter 177 to operate in the long-distance reception mode or the short-range reception mode.

First, the adaptive matching network 172 is a controller that calculates the amount of reception power by applying an optimal matching value according to an impedance condition to a signal, and may be provided to calculate the amount of required power to be received from the other device 200 by applying a matching value to a control signal received from the other device 200.

The rectifier 173 is a circuit for generating DC power from an input signal, and may be provided to convert a control signal transmitted from the adaptive matching network 172 into a DC voltage.

The RF signal detector 174 is a circuit that detects characteristics from an RF signal and outputs an RF characteristic signal according to the detected characteristics, and may be provided to output an RF characteristic signal from a control signal transmitted from the back-scatter modulator 171.

In this case, the RF signal detector 174 may detect characteristics of an RF signal received from an RF reception antenna (not shown) when connected to the RF reception antenna, and output an RF characteristic signal according to the detected characteristics.

The RF-DC converter 175 is a converter that converts an RF signal into a DC voltage, and may be provided to convert the RF characteristic signal output from the RF signal detector 174 into a DC voltage.

The DC-DC converter 177 is a converter that down-converts (or up-converts) the DC voltage into another DC voltage, and an end thereof may be connected to the battery B to convert a DC voltage obtained through conversion by the rectifier 173 or the RF-DC converter 175 into a DC voltage suitable for charging the battery B.

Such a back-scatter modulator 171, an adaptive matching network 172, the rectifier 173, the RF signal detector 174, the RF-DC converter 175, and the DC-DC converter 177 may be formed as either one circuit structure or a circuit module obtained by connecting these circuits to one another to generate required power, which is to be stored in the battery B, from a control signal received from the other device 200.

The communicator 190 may broadcast a message generated by the mode determiner 150 to the other device 200.

More specifically, the communicator 190 may broadcast an emergency request message, a normal request message or a rejection message generated according to a mode determined by the mode determiner 150 by transmitting the emergency request message, the normal request message or the rejection message to the other device 200.

Therefore, the wireless power receiving device 100 may determine required power on the basis of a result of monitoring the battery B and determine a reception mode according to the required power to receive power from the other device 200, thereby maximizing wireless power charging efficiency.

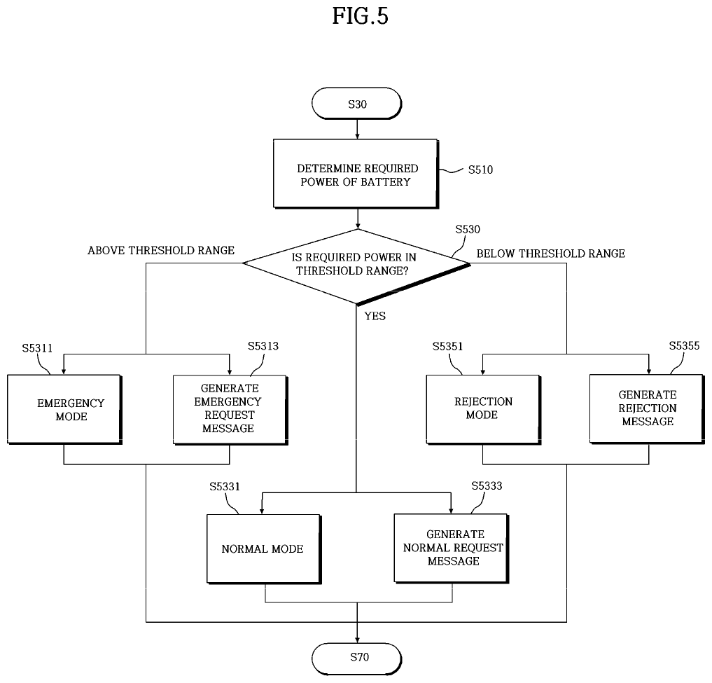

FIGS. 4 and 5 are flowcharts of a wireless power receiving method according to an embodiment of the present disclosure. The wireless power receiving method according to the embodiment of the present disclosure is performed by components that are the same as those of the wireless power receiving device 100 of FIGS. 1 to 3, and thus the components are assigned the same reference numerals as those assigned to the components of the wireless power receiving device 100 of FIGS. 1 to 3 and are not redundantly described here.

Referring to FIGS. 4 and 5, the wireless power receiving method according to the embodiment of the present disclosure is a method performed by the D2D-based wireless power receiving device 100 that wirelessly receives power from the other device 200, and includes an observation operation S10, an estimation operation S30, a mode determination operation S50, and a power reception operation S70.

First, the wireless power receiving device 100 performs the observation operation S10 of monitoring the battery B.

In this case, in the observation operation S10, the wireless power receiving device 100 may monitor the battery B by checking remaining capacity of the battery B at certain time intervals.

Thereafter, the wireless power receiving device 100 performs the estimation operation S30 of estimating usage and a workload of the battery B on the basis of a result of monitoring the battery B.

In addition, the wireless power receiving device 100 performs the mode determination operation S50 of determining required power of the battery B on the basis of the of usage and the workload, and determining a reception mode according to the required power.

In this case, the wireless power receiving device 100 may output the required power by inputting the usage and workload to a deep learning-based required-power output model.

In addition, the reception mode determined by the wireless power receiving device 100 may include an emergency mode for requesting the other device 200 to provide the required power through the short-range reception mode, a normal mode for requesting the other device 200 to provide the required power through the long-range reception mode, and a rejection mode for rejecting the required power from the other device 200.

When the required-power output model outputs the required power, the wireless power receiving device 100 may compare the required power with a threshold range, and may operate in the emergency mode when the required power is beyond the threshold range, operate in the normal mode when the required power is in the threshold range, and operate in the rejection mode when the required power is below the threshold range.

More specifically, the wireless power receiving device 100 may determine the required power output from the required-power output model (S510), and compare the determined required power with a preset threshold range (S530).

Here, when the required power is beyond the threshold voltage, the wireless power receiving device 100 may operate in the emergency mode (S5311), and generate an emergency request message (S5313).

When the required power is the threshold voltage, the wireless power receiving device 100 may operate in the normal mode (S5331), and generate a normal request message (S5333).

When the required power is below the threshold voltage, the wireless power receiving device 100 may operate in the rejection mode (S5351), and generate a rejection message (S5355).

Thereafter, the wireless power receiving device 100 performs power reception operation S70 of wirelessly receiving power from the other device 200 according to the reception mode.

Accordingly, the wireless power receiving device 100 may perform the wireless power receiving method to maximize wireless power charging efficiency.

According to an aspect of the present disclosure described above, wireless power charging efficiency can be maximized by providing a D2D-based wireless power receiving device and method.

In addition, by providing the D2D-based wireless power receiving device and method, the strength of power to be received from another device can be determined to configure an efficient wireless power transmission and reception system.

While various embodiments of the present disclosure have been illustrated and described herein, the present disclosure is not limited thereto and various modifications may be made by those of ordinary skill in the art without departing from the gist of the present disclosure as claimed in the accompanying claims. These modifications should not be understood separately from the scope and spirit of the present disclosure.

What is claimed is:

1. A wireless power receiving device based on device-to-device (D2D), comprising:
an observation part configured to monitor a battery;
an estimator configured to estimate usage and a workload of the battery on the basis of a result of monitoring the battery;
a mode determiner configured to determine required power of the battery on the basis of the usage and the workload, and determine a reception mode according to the required power; and
a power receiver configured to wirelessly receive power from another device according to the reception mode.

2. The wireless power receiving device of claim 1, wherein the observation part monitors the battery by checking remaining capacity of the battery at certain time intervals.

3. The wireless power receiving device of claim 1, wherein the mode determiner outputs the required power by inputting the usage and the workload to a deep learning-based required-power output model.

4. The wireless power receiving device of claim 3, wherein the reception mode comprises:
an emergency mode for requesting the other device to provide the required power through a short-range reception mode;
a normal mode for requesting the other device to provide the required power through a long-range reception mode; and
a rejection mode for rejecting the required power from the other device.

5. The wireless power receiving device of claim 4, wherein the mode determiner is configured to:
compare the required power with a threshold range when the required-power output model outputs the required power; and
operate the wireless power receiving device in the emergency mode when the required power is beyond the threshold range, operate the wireless power receiving device in the normal mode when the required power is in the threshold range, and operate the wireless power receiving device in the rejection mode when the required power is below the threshold range.

6. A wireless power receiving method performed by a device-to-device (D2D)-based wireless power receiving device, comprising:
an observation operation of monitoring a battery;
an estimation operation of estimating usage and a workload of the battery on the basis of a result of monitoring the battery;
a mode determination operation of determining required power of the battery on the basis of the usage and the workload, and determining a reception mode according to the required power; and
a power receiving operation of wirelessly receiving power from another device according to the reception mode.

7. The wireless power receiving method of claim 6, wherein the observation operation comprises monitoring the battery by checking remaining capacity of the battery at certain time intervals.

8. The wireless power receiving method of claim 6, wherein the mode determination operation comprises outputting the required power by inputting the usage and the workload to a deep learning-based required-power output model.

9. The wireless power receiving method of claim 8, wherein the reception mode comprises:
an emergency mode for requesting the other device to provide the required power through a short-range reception mode;
a normal mode for requesting the other device to provide the required power through a long-range reception mode; and
a rejection mode for rejecting the required power from the other device.

10. The wireless power receiving method of claim 9, wherein the mode determination operation comprises:
comparing the required power with a threshold range when the required-power output model outputs the required power; and
operating the wireless power receiving device in the emergency mode when the required power is beyond the threshold range, operating the wireless power receiving device in the normal mode when the required power is in the threshold range, and operating the wireless power receiving device in the rejection mode when the required power is below the threshold range.
